(19) United States
(12) Patent Application Publication
(10) Pub. No.: US 2013/0016478 A1
(43) Pub. Date: Jan. 17, 2013

(54) ELECTRONIC PACKAGE WITH THERMAL VIAS, AND FABRICATION PROCESS

(71) Applicants: Jean Gagnieux, Montaud (FR); Maxime Pailhes, La Buisse (FR)

(72) Inventors: Jean Gagnieux, Montaud (FR); Maxime Pailhes, La Buisse (FR)

(73) Assignee: STMICROELECTRONICS (GRENOBLE 2) SAS, Grenoble (FR)

(21) Appl. No.: 13/548,939

(22) Filed: Jul. 13, 2012

(30) Foreign Application Priority Data
Jul. 13, 2011 (FR) 1156418

(51) Int. Cl. H05K 7/20; H05K 3/30

(52) U.S. Cl. 361/719; 29/841

(57) ABSTRACT

An electronic package includes at least one heat-transfer element interposed between a front side of an integrated-circuit chip and a back side of a heat-transfer plate. An encapsulation block has a portion lying between the front side of the integrated-circuit chip and the back side of the heat-transfer plate. The portion embeds the heat-transfer element. Another heat transfer element is interposed between a front side of a electrical-connection support plate and a rim portion of the heat-transfer plate.

### PRIORITY CLAIM

This application claims priority from French Application for Patent No. 1156418 filed Jul. 13, 2011, the disclosure of which is hereby incorporated by reference.

### TECHNICAL FIELD

The present invention relates to the field of electronic packages that include integrated-circuit chips.

### BACKGROUND

Known packages include those which comprise: an electrical-connection support plate; at least one integrated-circuit chip having, peripherally on the front side of the integrated circuits, front connection pads for electrical connection, the back side of said chip being fastened to the front side of the support plate; electrical connection wires connected to the front contact pads on the chip and to front contact pads on the support plate; and an encapsulation block on the front side of the support plate, in which block the chip and the electrical connection wires are embedded.

For the purpose of dissipating the heat generated by the chip, such known packages may be fitted with a metal plate placed on the encapsulation block, the peripheral edge of which is embedded in the encapsulation block, and may be fitted with a metal heat sink bonded to the metal plate.

However, it turns out that such an arrangement is insufficiently effective, especially in the case when the amount of heat to be dissipated is large.

### SUMMARY

The invention proposes an electronic package that improves the heat dissipation conditions.

This electronic package comprises: an electrical-connection support plate; at least one integrated-circuit chip, the back side of which is fixed to the front side of the support plate; a heat-transfer plate extending above and at a certain distance from the front side of the integrated-circuit chip; at least one heat-transfer element interposed between the front side of the integrated-circuit chip and the back side of the heat-transfer plate; and an encapsulation block having a portion lying between the front side of the integrated-circuit chip and the back side of the heat-transfer plate and in which portion said heat-transfer element is embedded.

The package may comprise heat-transfer elements that are spaced apart and substantially of cylindrical shape.

The package may comprise heat-transfer elements that are spaced apart and, beside one another, and substantially of parallel elongate shapes.

Said heat-transfer element may comprise a thermally conductive adhesive.

The package may comprise electrical connection wires that connect front contact pads on the chip to front contact pads on the support plate, these electrical connection wires being embedded in said encapsulation block.

The heat-transfer plate may have at least one rim, it being possible for at least one fastening element to be interposed between this rim and the front side of the support plate.

Said heat-transfer element and said fastening element may be made of the same material.

The package may comprise a heat sink fastened above the heat-transfer plate of the lid.

The heat sink may be fastened by means of a layer of adhesive made of a thermally conductive material.

A process for fabricating an electronic package is also proposed.

This process may comprise: fastening the back side of at least one integrated-circuit chip to the front side of a support plate; depositing at least one droplet, made of a thermally conductive deformable material, on the front side of the integrated-circuit chip; fitting a heat-transfer plate, this heat-transfer plate being placed on said droplet and compressing the latter, and curing this droplet so as to form a heat-transfer element between the integrated-circuit chip and the heat-transfer plate; and producing an encapsulation block having a portion between the front side of the integrated-circuit chip and the back side of the heat-transfer plate and in which lying block said heat-transfer element is embedded.

The process may further comprise: depositing at least one droplet of a deformable material on the front side of the support plate; then fitting the heat-transfer plate, a rim of the heat-transfer plate being placed on this droplet and compressing the latter; and curing this droplet so as to form a fastening element between the integrated-circuit chip and the heat-transfer plate.

This process may comprise: concomitantly depositing the droplet intended to form the heat-transfer element and the droplet intended to form the fastening element.

The process may comprise: producing the encapsulation block by injecting material, the heat-transfer elements being spaced apart and beside one another, of substantially parallel elongate shapes and placed along the flow direction of the injected material.

The process may comprise bonding the electrical connection wires that connect the front contact pads on the chip to the front contact pads on the support plate before the heat-transfer plate is fitted.

The process may comprise fastening a heat sink to the heat-transfer plate via a layer of thermally conductive material.

### BRIEF DESCRIPTION OF THE DRAWINGS

An electronic package will now be described by way of non-limiting example and illustrated by the appended drawing in which:

FIG. 1 shows a cross section through an electronic package;

FIG. 2 shows a partial cross section, when viewed flat-on, of the package of FIG. 1 according to a first embodiment;

FIG. 3 shows a partial cross section, when viewed flat-on, of the package of FIG. 1 according to another embodiment; and

FIGS. 4 to 7 show steps in the fabrication of the package of FIG. 1.

### DETAILED DESCRIPTION OF THE DRAWINGS

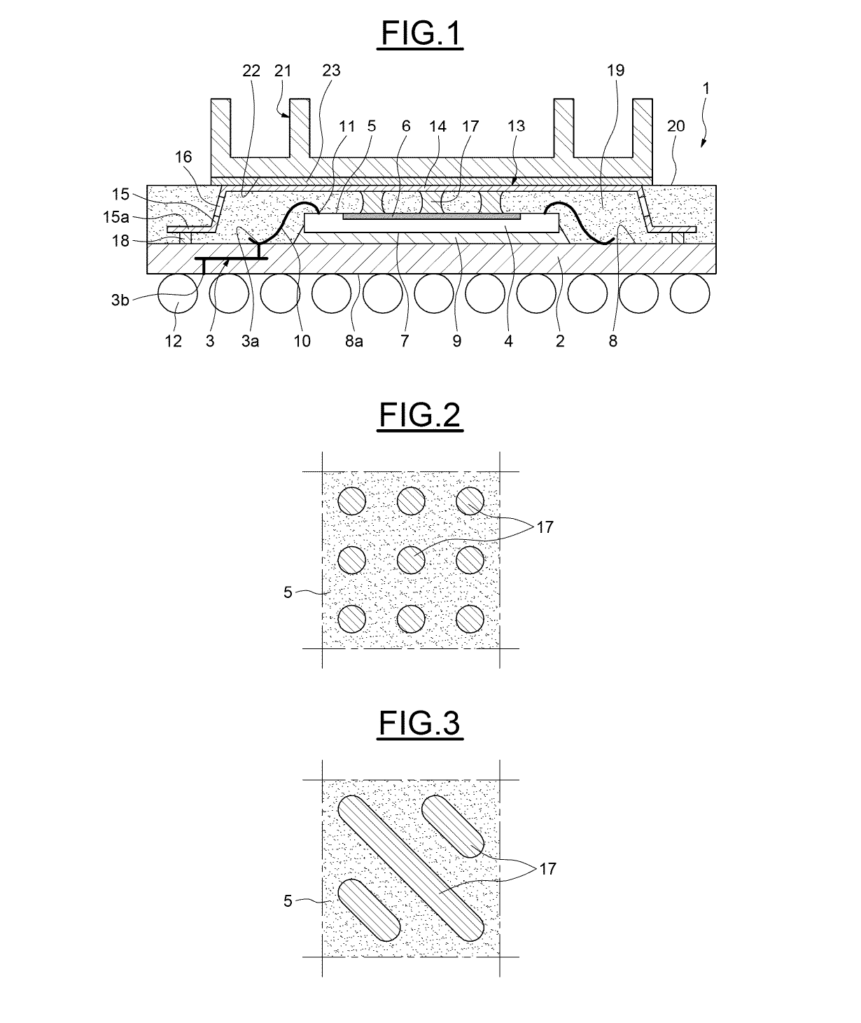

As illustrated in FIG. 1, an electronic package 1 comprises: an electrical-connection support plate 2, which includes an integrated electrical interconnection network 3; and an integrated-circuit chip 4 having, on the front side 5 thereof, integrated circuits 6, the back side 7 of said chip being fastened to a central portion of the front side 8 of the support plate 2 by means of a layer of adhesive 9.

Electrical connection wires 10 connect front contact pads 11 on the chip 3, which are provided on the periphery of the front side 5 thereof, and front contact pads 3a of the electrical interconnection network 3 on the support plate 2, these contact pads being provided on the front side 8 thereof.

Arranged on the back side 8a of the support plate 2 are external electrical connection balls 12 placed on rear contact pads 3b of the interconnection network 3 of the support plate 2.

The electronic package 1 also comprises a heat-transfer plate 13, for example made of metal, in particular nickel-plated copper, which has a flat central portion 14 that extends above and at a certain distance from the chip 4, and connection wires 10 parallel to the front side 8 of the support plate 2, and which has, on the periphery and away from the connection wires 10, one or more rims 15 bent over towards the front side 8 of the support plate 2 and having one or more terminal portions 15a parallel to the front side 8 of the support plate 2, these rims being designed so as to leave flow apertures 16.

Interposed between the front side 5 of the integrated-circuit chip 4 and the rear side of the central portion 14 of the heat-transfer plate 13 is a plurality of heat-transfer elements 17 judicially placed at points where there are not electrical connection wires 10.

According to one embodiment, illustrated in FIG. 2, the heat-transfer elements 17 may be substantially of cylindrical shape. According to another embodiment, illustrated in FIG. 3, the heat-transfer elements 17 may be of substantially elongate shape and arranged so as to be mutually parallel, one beside another.

According to one embodiment, the terminal portions 15a of the heat-transfer plate 13 may bear on the support plate 2. According to another embodiment, illustrated in FIG. 1, a plurality of fastening elements 18 may be interposed between the front side 5 of the support plate 2 and the back side of the terminal portion or portions 15a of the heat-transfer plate 13.

The heat-transfer elements 17 and the fastening elements 18 are for example made of the same material, in particular formed from a cured epoxy adhesive filled with metal particles, for example silver, copper or aluminum particles.

The electronic package 1 further comprises an encapsulation block 19 made of a material such as, for example, a cured epoxy resin, which block is formed on the front side 8 of the support plate 2 and in which the integrated-circuit chip 4, the electrical connection wires 10, the rims 14 of the metal plate 13, the heat-transfer elements 17 and the fastening elements 18 are all embedded. The encapsulation block 19 has a front side 20 parallel to the front side 8 of the support plate 2 and lying in the plane of the front side of the central portion 14 of the heat-transfer plate 13.

The electronic package 1 may be fitted with a heat sink 21 that has a flat back face 22 fastened to the flat front side of the central portion 14 of the heat-transfer plate 13 and possibly to the flat front side 20 of the encapsulation block 19, via a layer of thermally conductive adhesive 23.

It follows from the foregoing description that the heat-transfer elements 17 form heat-transfer vias between the integrated-circuit chip 4 and the heat-transfer plate 13 and that, as a consequence, the heat generated by the integrated-circuit chip 4 can be at least partly dissipated towards the front by the heat sink 22 preferentially via the heat-transfer elements and the metal plate 13, the metal plate 13 and the layer of thermally conductive adhesive 23 contributing to distributing the heat over the surface of the back face 22 of the heat sink 21.

The distribution of the heat-transfer elements 17 may be regular or irregular. The positions on the front side 5 of the integrated-circuit chip 4 and the cross sections of the heat-transfer elements 17 may be adapted to the heat flux to be discharged over various areas of this front side 5.

One method of fabricating the electronic package 1, which may result from the wafer-scale fabrication of a plurality of electronic packages 1 on a common electrical-connection support plate 24, which includes locations corresponding to the electrical-connection support plate 2, will now be described.

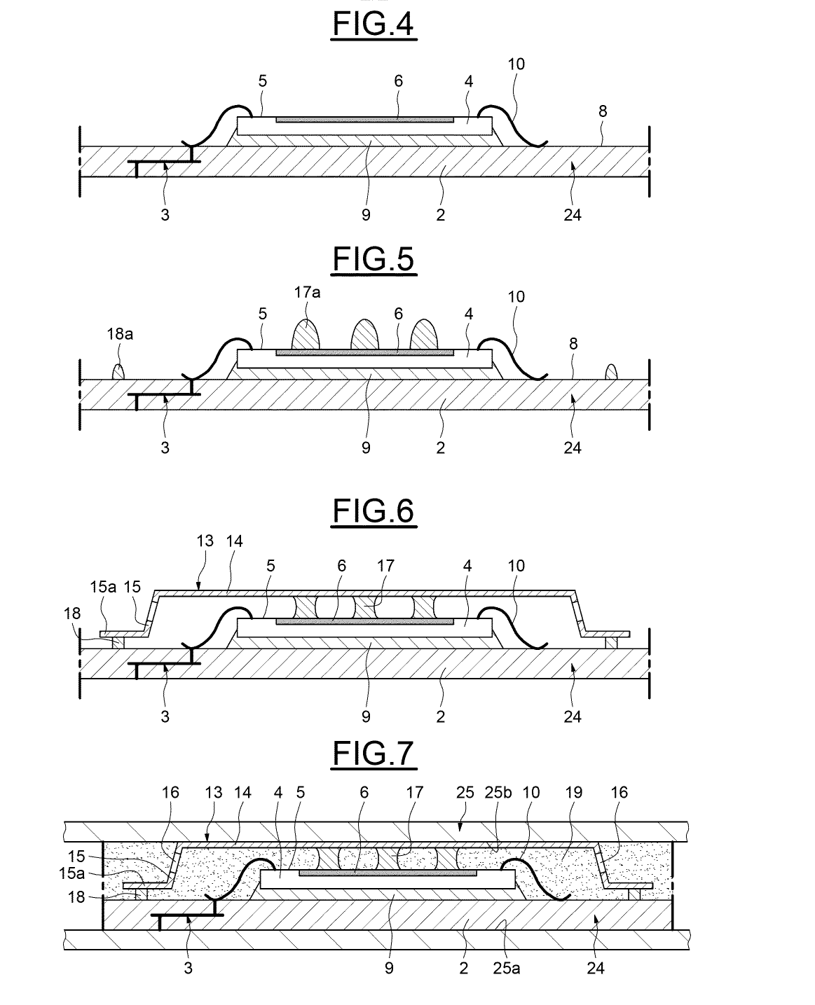

As illustrated in FIG. 4, the integrated-circuit chip 4 is installed, at each location, on the support plate 2 by means of the layer of adhesive 9.

Next, as illustrated in FIG. 5, droplets 17A of a thermally conductive deformable material, in particular droplets of a liquid or pasty thermally conductive adhesive, are deposited, at each location, on the front side 5 of the integrated-circuit chip 4, at the places where the heat-transfer elements 17 are to be produced, the height of these droplets 17A being greater than the gap between the central portion 14 of the heat-transfer plate 13 and the front side 5 of the integrated-circuit chip 4 of the package 1 to be produced.

Concomitantly, droplets 18A of a thermally conductive deformable material, particular droplets 18A of the same liquid or pasty thermally conductive adhesive, are deposited, advantageously using the same deposition machine, on the front side 8 of the support plate 2 at places where the fastening elements 18 are to be produced, the height of these droplets 18A being greater than the gap between the terminal portions 15a of the heat-transfer plate 13 and the front side 8 of the support plate 2 of the package 1 to be produced.

Next, as illustrated in FIG. 6, the heat-transfer plate 13 is fitted, at each location, by compressing the adhesive droplets 17A and 18A and bringing this heat-transfer plate 13 to the desired position relative to the support plate 2. The adhesive is then cured, for example in an oven, so as to obtain the heat-transfer elements 17 and the fastening elements 18.

Next, as illustrated in FIG. 7, the whole assembly obtained above is placed in the cavity of a mold 25, in a position such that the back side 8a of the support plate 2 and the front side of the central portion 14 of the heat-transfer plate 13 are against opposed parallel faces 25a and 25b of this cavity. The material for wafer-scale production of the encapsulation block 19 is then injected, this material penetrating beneath the heat-transfer plate 13 through the apertures 16 made in the rims 15 of said plate. In the case when the heat-transfer elements 17 are elongate, as illustrated in FIG. 3, it is desirable for these heat-transfer elements 17 to be elongate in the direction of flow of the injected material. After the material has cured, the demolding operation is carried out.

Next, the electrical connections balls 12 are placed on the back side 8a of the support plate 2.

The wafer-scale electronic packages 1 obtained are then singulated, for example by sawing.

The heat sink 21 may be fitted either before singulation or afterwards.

The present invention is not limited to the examples described above. Many other alternative embodiments and combinations of the arrangements described are possible, without departing from the scope defined by the appended claims.

What is claimed is:

1. An electronic package, comprising:
an electrical-connection support plate;
at least one integrated-circuit chip having a back side fixed to a front side of the support plate;
a heat-transfer plate extending above and at a certain distance from a front side of the integrated-circuit chip ;
at least one heat-transfer element interposed between the front side of the integrated-circuit chip and the back side of the heat-transfer plate; and
an encapsulation block having a portion lying between the front side of the integrated-circuit chip and the back side of the heat-transfer plate and in which portion said heat-transfer element is embedded.

2. The package according to claim 1, wherein said at least one heat-transfer element comprise a plurality of heat-transfer elements that are spaced apart and substantially of cylindrical shape.

3. The package according to claim 1, wherein said at least one heat-transfer element comprise a plurality of heat-transfer elements that are spaced apart and beside one another, and substantially of parallel elongate shapes.

4. The package according to claim 1, wherein said heat-transfer element comprises a thermally conductive adhesive.

5. The package according to claim 1, further comprising electrical connection wires connecting front contact pads on the integrated-circuit chip to front contact pads on the support plate, these electrical connection wires being embedded in said encapsulation block.

6. The package according to claim 1, wherein the heat-transfer plate has at least one rim and in which at least one fastening element is interposed between the rim and the front side of the support plate.

7. The package according to claim 6, wherein said heat-transfer element and said fastening element are made of the same material.

8. The package according to claim 1, further comprising a heat sink fastened above the heat-transfer plate.

9. The package according to claim 8, wherein the heat sink is fastened via a layer of adhesive made of a thermally conductive material.

10. A process for fabricating an electronic package, comprising:
fastening a back side of at least one integrated-circuit chip to a front side of a support plate;
depositing at least one droplet, made of a thermally conductive deformable material, on a front side of the integrated-circuit chip;
placing a heat-transfer plate on said droplet;
compressing the droplet;
curing the compressed droplet so as to form a heat-transfer element between the integrated-circuit chip and the heat-transfer plate; and
producing an encapsulation block having a portion between the front side of the integrated-circuit chip and the back side of the heat-transfer plate, said encapsulation block embedding said heat-transfer element.

11. The process according to claim 10, further comprising:
depositing at least one droplet of a deformable material on the front side of the support plate;
placing a rim of the heat-transfer plate on the droplet;
compressing the droplet; and
curing the droplet so as to form a fastening element between the support plate and the heat-transfer plate.

12. The process according to claim 11, further comprising:
concomitantly depositing the droplet intended to form the heat-transfer element and the droplet intended to form the fastening element.

13. The process according to claim 10, further comprising:
producing the encapsulation block by injecting material, the heat-transfer elements being spaced apart and beside one another, of substantially parallel elongate shapes and placed along the flow direction of the injected material.

14. The process according to claim 10, which comprises:
bonding electrical connection wires that connect front contact pads on the chip to front contact pads on the support plate before the placing the heat-transfer plate.

15. The process according to claim 10, further comprising:
fastening a heat sink to the heat-transfer plate via a layer of thermally conductive material.

16. An electronic package, comprising:
an electrical-connection support plate;
at least one integrated-circuit chip having a back side fixed to a front side of the support plate;
a heat-transfer plate having a central portion and a rim portion;
a first heat-transfer element interposed between the central portion of the heat-transfer plate and a front side of the integrated-circuit chip;
a second heat-transfer element interposed between the rim portion of the heat-transfer plate and the front side of the electrical-connection support plate; and
an encapsulation block having a first portion lying between the front side of the integrated-circuit chip and a back side of the heat-transfer plate and in which portion said first heat-transfer element is embedded and having a second portion lying between the front side of the electrical-connection support plate and the back side of the heat-transfer plate and in which portion said second heat-transfer element is embedded.

17. The package according to claim 16, wherein said first heat-transfer element comprises a plurality of first heat-transfer elements that are spaced apart and each having a substantially cylindrical shape.

18. The package according to claim 16, wherein said first heat-transfer element comprises a plurality of first heat-transfer elements that are spaced apart and each having a substantially elongate shape and arranged in parallel.
